(19) United States
(12) Patent Application Publication
(10) Pub. No.: US 2013/0148091 A1
(43) Pub. Date: Jun. 13, 2013

(54) LITHOGRAPHY APPARATUS AND METHOD, AND METHOD OF MANUFACTURING ARTICLE

(71) Applicant: Canon Kabushiki Kaisha, Tokyo (JP)

(72) Inventors: Koichi Sentoku, Kawachi-gun (JP); Shigeki Ogawa, Utsunomiya-shi (JP); Hideki Ina, Tokyo (JP)

(73) Assignee: CANON KABUSHIKI KAISHA, Tokyo (JP)

(21) Appl. No.: 13/713,631

(22) Filed: Dec. 13, 2012

(30) Foreign Application Priority Data
Dec. 13, 2011 (JP) 2011-272748
Nov. 28, 2012 (JP) 2012-260341

(51) Int. Cl. G03F 7/20

(52) U.S. Cl. CPC G03F 7/70141
USPC 355/67

(57) ABSTRACT

A lithography apparatus which positions a substrate based on measurement of a position of an alignment mark on the substrate to form a pattern on the substrate. The apparatus includes an acquisition unit configured to acquire a first required alignment precision in a first direction, and a second required alignment precision in a second direction different from the first direction, and a controller configured to determine, based on the first required alignment precision, a first condition for a first measurement process of measuring a position of an alignment mark in the first direction, to determine, based on the second required alignment precision, a second condition for a second measurement process of measuring a position of an alignment mark in the second direction.

### BACKGROUND OF THE INVENTION

1. Field of the Invention

The present invention relates to a lithography apparatus and method of forming a pattern on a substrate, and a method of manufacturing an article.

2. Description of the Related Art

Japanese Patent Laid-Open No. 2003-92246 describes an alignment mark including first measurement marks X1, X2, X3, and X4 and second measurement marks Y1 and Y2. The first measurement marks X1, X2, X3, and X4 are used to measure the position of the alignment mark in the X-direction. The second measurement marks Y1 and Y2 are used to measure the position of the alignment mark in the Y-direction. The second measurement marks Y1 and Y2 are arranged outside the region in which the first measurement marks X1, X2, X3, and X4 are arranged, and parallel to the direction in which scribe lines extend. The position of the alignment mark in the X-direction is the average of the positions of the first measurement marks X1, X2, X3, and X4. The position of the alignment mark in the Y-direction is the average of the positions of the second measurement marks Y1 and Y2.

A maximum precision is not always required in both the X- and Y-directions. If, for example, a maximum precision is required in one of the X- and Y-directions, while a precision lower than the maximum precision suffices in the other direction, measurement with the maximum precision in both the X- and Y-directions is disadvantageous in terms of the throughput.

### SUMMARY OF THE INVENTION

The present invention provides, for example, a lithography apparatus advantageous in terms of throughput.

One of the aspects of the present invention provides a lithography apparatus which positions a substrate based on measurement of a position of an alignment mark formed on the substrate to form a pattern on the substrate, the apparatus comprising: an acquisition unit configured to acquire a first required alignment precision in a first direction, and a second required alignment precision in a second direction different from the first direction; and a controller configured to determine, based on the first required alignment precision, a first condition for a first measurement process of measuring a position of an alignment mark in the first direction, to determine, based on the second required alignment precision, a second condition for a second measurement process of measuring a position of an alignment mark in the second direction, to control execution of the first measurement process in accordance with the first condition, and to control execution of the second measurement process in accordance with the second condition.

Further features of the present invention will become apparent from the following description of exemplary embodiments with reference to the attached drawings.

### BRIEF DESCRIPTION OF THE DRAWINGS

FIG. 1 is a view illustrating an example of the arrangement of alignment marks measured in the first embodiment;

FIG. 2 is a view illustrating the configuration of a charged particle beam exposure apparatus;

FIG. 3 is a view illustrating an array of shot regions and alignment marks;

FIG. 4 is a view illustrating the arrangement of an alignment scope;

FIG. 5 is a flowchart for explaining the operation of the exposure apparatus and an exposure method in the first embodiment;

FIGS. 6A and 6B are views illustrating alignment marks;

FIG. 7 is a view illustrating an alignment mark;

FIG. 8 is a view illustrating another example of the arrangement of alignment marks measured in the first embodiment;

FIGS. 9A to 9D are views illustrating alignment marks and detection signals obtained by these marks in the second embodiment;

FIG. 10 is a view for explaining the third embodiment;

FIG. 11 is a block diagram for explaining the fourth embodiment; and

FIG. 12 shows an example of the two dimensional mark.

### DESCRIPTION OF THE EMBODIMENTS

### First Embodiment

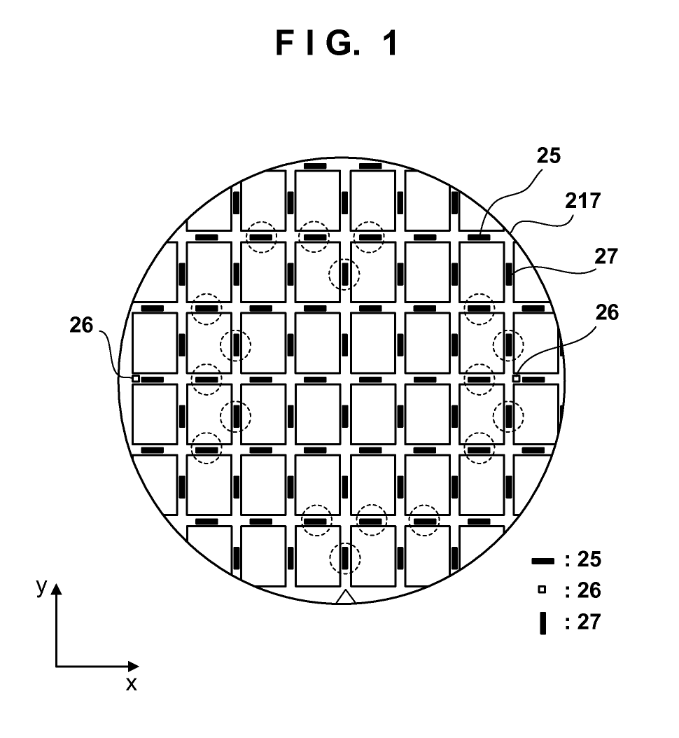

The first embodiment of the present invention will be described with reference to FIGS. 1 to 8. The first embodiment relates to an apparatus and method which detect the position of an alignment mark formed on a substrate such as a wafer, and form a pattern on the substrate while aligning the substrate based on the detection result. A pattern can be formed on the substrate by, for example, an exposure of the substrate to radiant energy or imprinting on the substrate in that case. Note that the exposure of the substrate to radiant energy includes not only irradiating the substrate with light to form a latent image on a photosensitive material (resist) on the substrate, but also irradiating the substrate with a charged particle beam such as an electron beam to form a latent image on a photosensitive material on the substrate. By developing the photosensitive material having the latent image formed on it, a physical pattern (that is, a resist pattern) is formed. The following embodiments will provide a practical example in which a charged particle beam exposure apparatus (drawing apparatus) which irradiates a substrate with a charged particle beam to form a latent image on a photosensitive material on the substrate is used. However, the present invention is also applicable to the use of a light exposure apparatus which irradiates a substrate with light to form a latent image on a photosensitive material on the substrate. The present invention is moreover applicable to the use of other lithography apparatuses such as an imprint apparatus which forms the pattern of an imprint material on a substrate.

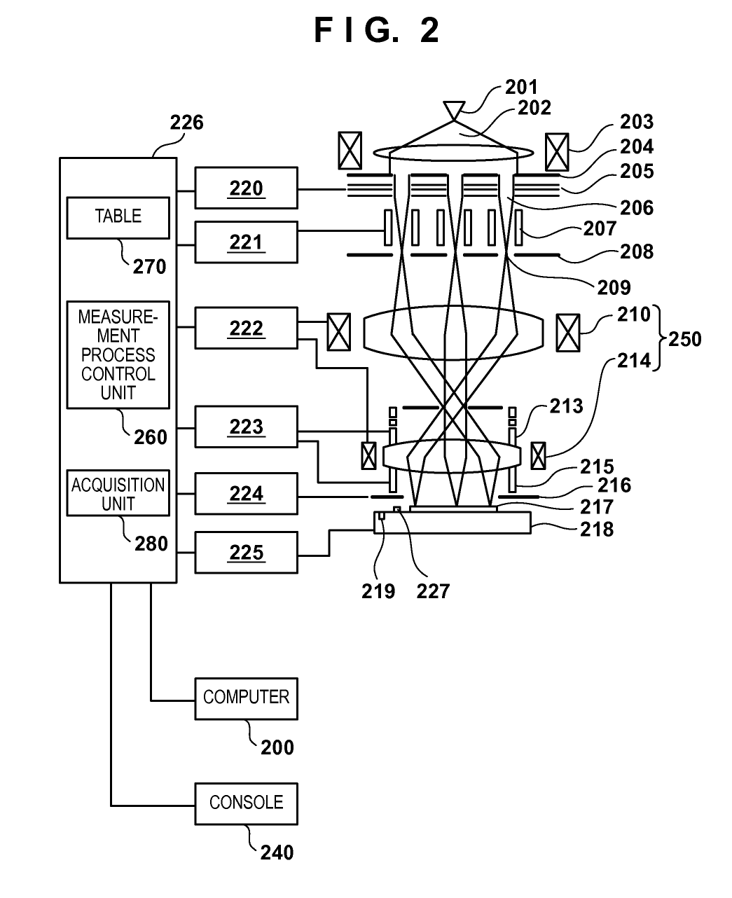

An exemplary charged particle beam exposure apparatus will be described below with reference to FIG. 2. An electron beam 202 emitted by the crossover of an electron gun 201 is converted into a nearly collimated electron beam by a condenser lens 203. The electron beam 202 nearly collimated by the condenser lens 203 is split into a plurality of electron beams 206 by an aperture array 204. The plurality of electron beams 206 form a plurality of intermediate images 209, respectively, of the crossover of the electron gun 201 in the vicinities of blanking apertures 208 by the action of a lens array 205 driven by a focus control circuit 220. The positions of the intermediate images 209 in the axial direction can be adjusted by controlling the powers of individual lenses which constitute the lens array 205. Upon application of a voltage to each blanker of a blanking array 207, the positions at which the intermediate images 209 are formed move in a direction perpendicular to the axial direction. With this operation, the electron beams 206 are blocked by the blanking apertures 208. On the other hand, when no voltage is applied to each blanker of the blanking array 207, the electron beams 206 are guided onto a substrate 217 while the positions at which the intermediate images 209 are formed remain the same. This makes it possible to control whether to guide the electron beams 206 onto the substrate 217, that is, ON/OFF of the electron beams 206.

The intermediate images 209 formed in the vicinities of the blanking apertures 208 are projected onto the substrate 217 set on a substrate stage 218 by a projection system 250 including a first projection lens 210 and second projection lens 214. The projection system 250 is driven by a lens control circuit 222 so as to match the rear focal position of the first projection lens 210 with the front focal position of the second projection lens 214. The electron beams 206 which form the intermediate images 209, respectively, are collectively deflected and positioned by a main deflector 213 and a sub-deflector 215. For example, the deflection width of the main deflector 213 can be set wide, while that of the sub-deflector 215 can be set narrow. An irradiation amount control circuit 221 controls the turning ON/OFF of the electron beams 206 using the blankers, respectively, of the blanking array 207 under the control of a controller 226 based on pattern data. A deflection control circuit 223 controls the deflection operations of the main deflector 213 and sub-deflector 215 under the control of the controller 226 based on the pattern data. A stage control circuit 225 controls the positioning operation of the substrate stage 218 under the control of the controller 226 based on the pattern data. A pattern is drawn on the substrate 217 upon the ON/OFF control of the electron beams 206 using the blankers, respectively, of the blanking array 207, the control of the deflection operations of the main deflector 213 and sub-deflector 215, and the control of the positioning operation of the substrate stage 218 using the stage control circuit 225. The controller 226 can be connected to a computer 200 which supplies drawing data to the controller 226.

A position measurement mark 227 and a Faraday cup 219 are arranged on the substrate stage 218. An electron detector 216 is arranged above the substrate stage 218. A signal detected by the electron detector 216 is processed by a signal processing circuit 224 to detect the amount of the electron beam.

The controller 226 can be connected to the computer 200 which supplies drawing data to the controller 226, and a console 240 which allows input of various types of data to the controller 226. The controller 226 includes an acquisition unit 280 and measurement process control unit 260. The acquisition unit 280 acquires a first required alignment (overlay) precision in the X-direction (first direction), and a second required alignment (overlay) precision in the Y-direction (second direction) different from the X-direction (first direction). Note that the first and second directions can be different directions (two directions), which are typically orthogonal to each other.

The controller 226 can acquire first and second required alignment precisions from the computer 200 or console 240. The measurement process control unit 260 determines a first condition for a first measurement process of detecting the position of an alignment mark in the X-direction, based on the first required alignment precision. The measurement process control unit 260 also determines a second condition for a second measurement process of detecting the position of an alignment mark in the Y-direction, based on the second required alignment precision. The measurement process control unit 260 then controls execution of the first measurement process in accordance with the first condition, and controls execution of the second measurement process in accordance with the second condition. The measurement process control unit 260 can determine a first condition based on the first required alignment precision, and a second condition based on the second required alignment precision by looking up, for example, a table 270. The table 270 can include, for example, a plurality of required alignment precisions of different levels, and a plurality of conditions (conditions for measurement processes) corresponding to the plurality of required alignment precisions of different levels, respectively.

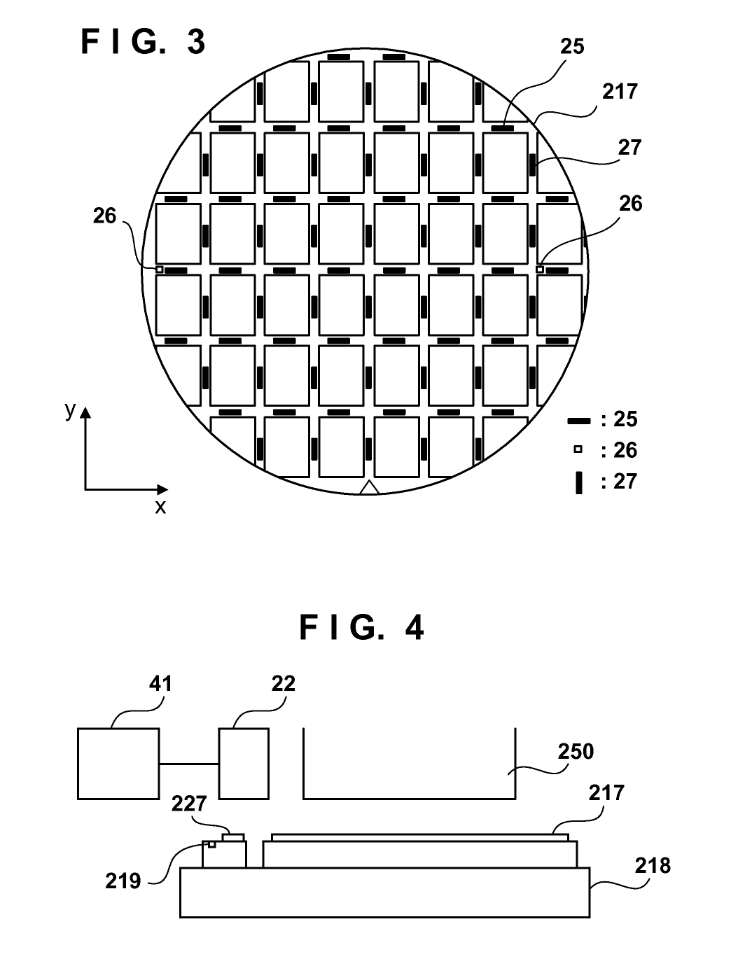

FIG. 3 illustrates an array of shot regions and alignment marks 25, 26, and 27 on the substrate 217. Note that a circuit pattern is formed in each shot region. The alignment marks 25 are used to align the substrate 217 in the X-direction (first direction). The alignment marks 27 are used to align the substrate 217 in the Y-direction (second direction). The alignment marks 26 are used for rough alignment. FIG. 4 illustrates a more detailed configuration of the portion surrounding the substrate 217 in the charged particle beam exposure apparatus shown in FIG. 2. An off-axis alignment scope 22 is arranged near the projection system 250. The positions of the alignment marks 25, 26, and 27 can be detected by detecting, by the alignment scope 22, images of a plurality of alignment marks formed on the substrate 217, and processing the images by a processor 41.

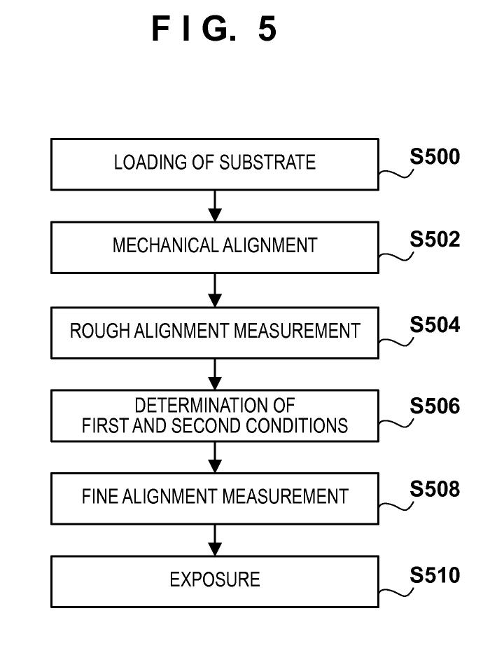

The operation of the exposure apparatus and an exposure method in the first embodiment will be described below with reference to FIG. 5. First, in step S500, a substrate 217 is loaded onto a substrate chuck 401 on the substrate stage 218. In step S502, mechanical alignment of the substrate 217 is performed. In step S504, rough alignment measurement is performed using the alignment mark 26 illustrated in FIG. 3.

In step S506, the measurement process control unit 260 determines a first condition for a first measurement process of detecting the position of the alignment mark 25 in the X-direction, based on the first required alignment precision acquired by the acquisition unit 280. In step S506, the measurement process control unit 260 also determines a second condition for a second measurement process of detecting the position of the alignment mark 26 in the Y-direction, based on the second required alignment precision acquired by the acquisition unit 280. Although the acquisition unit 280 acquires first and second required alignment precisions at arbitrary timings, it can acquire these precisions at, for example, the start of the process shown in FIG. 5.

In step S508, the measurement process control unit 260 executes fine alignment measurement using the alignment marks 25 and 27 in accordance with the first and second conditions determined in step S506. That is, the measurement process control unit 260 controls execution of the first measurement process in accordance with the first condition, and controls execution of the second measurement process in accordance with the second condition. In the first and second measurement processes, the alignment marks 25 and 27 are observed through the alignment scope 22, and the position of the alignment mark 25 in the X- and Y-directions is determined by the processor 41. Such a process is executed for pluralities of alignment marks 25 and 27.

In step S510, the substrate 217 is exposed to light while being aligned based on the result of the fine alignment measurement (the positions of the alignment marks 25 and 27). Note that the parallel eccentricities, rotations, and magnifications of all shot regions formed on the substrate 217 can be calculated by statistically processing the measurement results of the positions of the pluralities of alignment marks 25 and 27 obtained in step S508. A method of performing alignment upon calculating such information is called global alignment. In this case, one or more alignment marks 25 and one or more alignment marks 27 can be formed on scribe lines in each shot region.

A practical example of the first measurement process based on the first condition, and the second measurement process based on the second condition will be given below. Let √a:1 be the ratio between the first required alignment precision in the X-direction (first direction) and the second required alignment precision in the Y-direction (second direction). Also, let nx be the number of alignment marks 25 used for position detection in the X-direction, and ny be the number of alignment marks 27 used for position detection in the Y-direction. Then, we have:

√a:1=√nx:√ny (1)

This means that as the number of alignment marks used for position detection increases, the position detection precision improves, so the alignment precision also improves. Note that the alignment precision is, for example, the reciprocal of the alignment error, and becomes better as its numerical value increases. Similarly, the position detection precision is, for example, the reciprocal of the position detection error, and becomes better as its numerical value increases.

In the first embodiment, the ratio between the numbers of alignment marks 25 and 27 used for position detection is determined as the first and second conditions based on equation (1). Typically, the number of alignment marks in one of the X- and Y-directions, in which a higher alignment precision is required, is determined by process optimization, and the number of alignment marks in the other direction is determined in accordance with equation (1). Alternatively, the number of alignment marks in one of the X- and Y-directions, in which a higher alignment precision is required, may be determined to be sufficiently large based on an empirical rule, and the number of alignment marks in the other direction may be determined in accordance with equation (1). In this case, the alignment precisions of the exposed substrate can be evaluated, and the number of alignment marks in one of the X- and Y-directions, in which a higher alignment precision is required, can be changed based on the evaluation result. In response to this, the number of alignment marks in the other direction can be determined in accordance with equation (1).

As described above, in the first embodiment, the measurement process control unit 260 determines a first condition in the X-direction based on the first required alignment precision in the X-direction, and a second condition in the Y-direction based on the second required alignment precision in the Y-direction. By individually determining a first condition for alignment (or position detection) in the X-direction, and a second condition for alignment (or position detection) in the Y-direction in this way, the throughput can be improved while the required alignment precisions are satisfied.

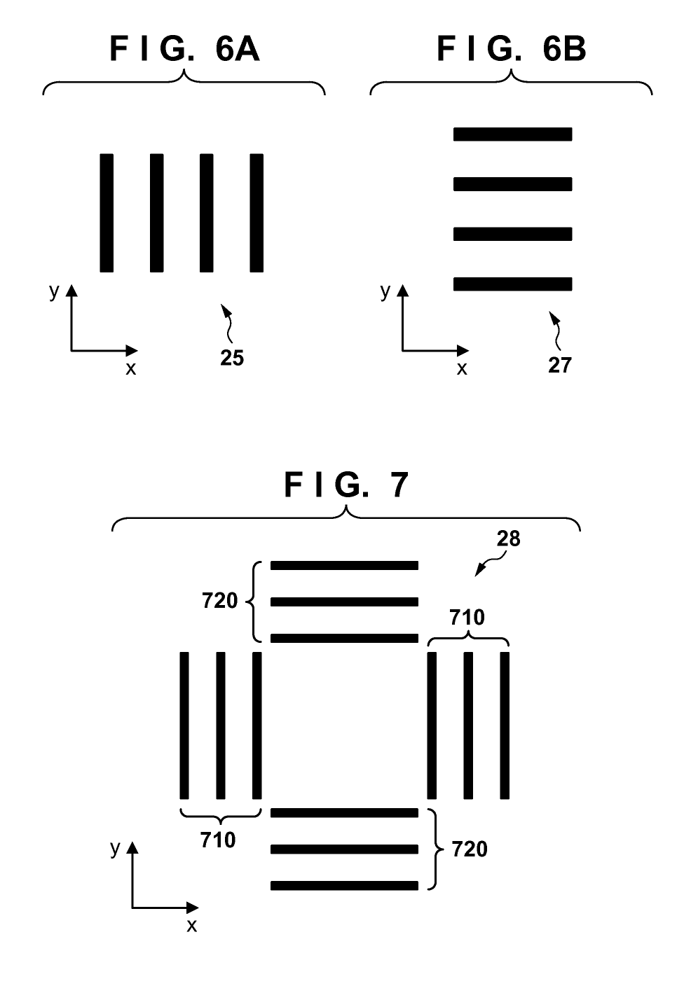

A practical example will be given below with reference to FIG. 1. Assume herein that the ratio between the first required alignment precision in the X-direction (first direction) and the second required alignment precision in the Y-direction (second direction) is √2:1. Referring to FIG. 1, the alignment marks 25 are used to align the substrate 217 in the X-direction (first direction), and a detailed example of its configuration is shown in FIG. 6A. The alignment marks 27 are used to align the substrate 217 in the Y-direction (second direction), and a detailed example of its configuration is shown in FIG. 6B. In an example shown in FIG. 1, 12 alignment marks 25 are used for alignment in the X-direction (first direction), and six alignment marks 25 are used for alignment in the Y-direction (second direction). Accordingly, these conditions satisfy equation (1) as per:

√12:√6=√2:1 (2)

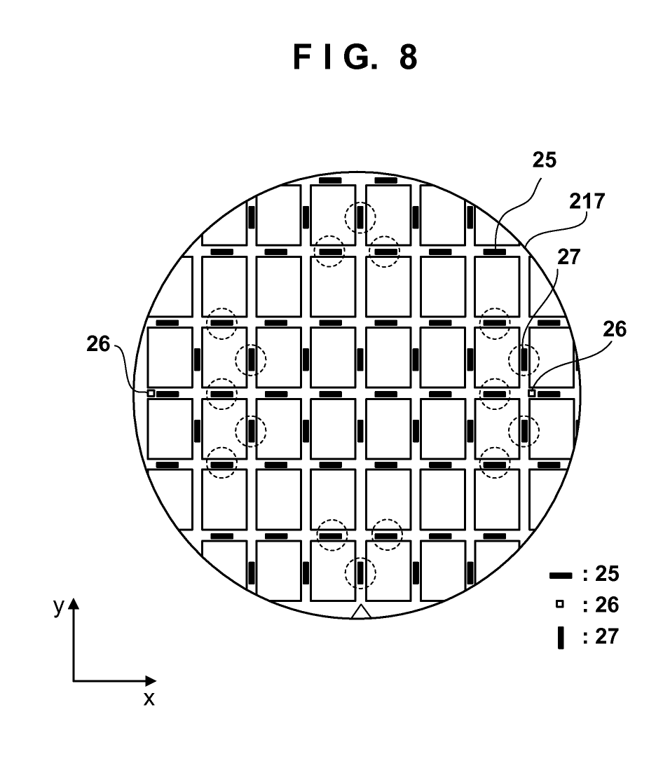

Although the alignment marks 25 and 27 are formed in each shot region in an example shown in FIG. 1, the number of alignment marks may be decreased, as illustrated in FIG. 8, as long as the required alignment precisions are low. In an example shown in FIG. 8, alignment marks 25 are formed in all shot regions, while alignment marks 27 are formed only in some of a plurality of shot regions. Decreasing the number of alignment marks in this way makes it possible to shorten the time taken to form the alignment marks.

The first embodiment is also applicable to alignment of a substrate 217 on which alignment marks 28 as illustrated in FIG. 7 are formed. The alignment marks 28 can be used for position detection in both the X- and Y-directions. Six linear patterns 710 extending parallel to the Y-direction are used to detect the position of the alignment mark 28 in the X-direction. Six linear patterns 720 extending parallel to the X-direction are used to detect the position of the alignment mark 28 in the Y-direction. When the substrate 217 on which the alignment marks 28 illustrated in FIG. 7 are formed is processed as well, the number of alignment marks 28 used for alignment in the X-direction, and the number of alignment marks 28 used for alignment in the Y-direction can be determined individually. All or some of the alignment marks 28 used for alignment in the X-direction, and all or some of the alignment marks 28 used for alignment in the Y-direction may be the same as or different from each other.

Note that an example of a process in which different required alignment precisions are set in the X- and Y-directions is cutting lithography. As another, more common example, the required alignment precisions in the X- and Y-directions are determined based on, for example, the shape of a circuit pattern, and are generally different from each other.

### Second Embodiment

The second embodiment of the present invention will be described below. Details which are not particularly referred to herein can be the same as in the first embodiment. In the second embodiment, a measurement process control unit 260 determines the count of reception of the pieces of information of alignment marks used for alignment in the X-direction using an alignment scope 22, based on the first required alignment precision. The measurement process control unit 260 also determines the count of reception of the pieces of information of alignment marks used for alignment in the Y-direction using the alignment scope 22, based on the second required alignment precision. Note that the alignment marks used for alignment in the X-direction, and the alignment marks used for alignment in the Y-direction may be the same as or different from each other.

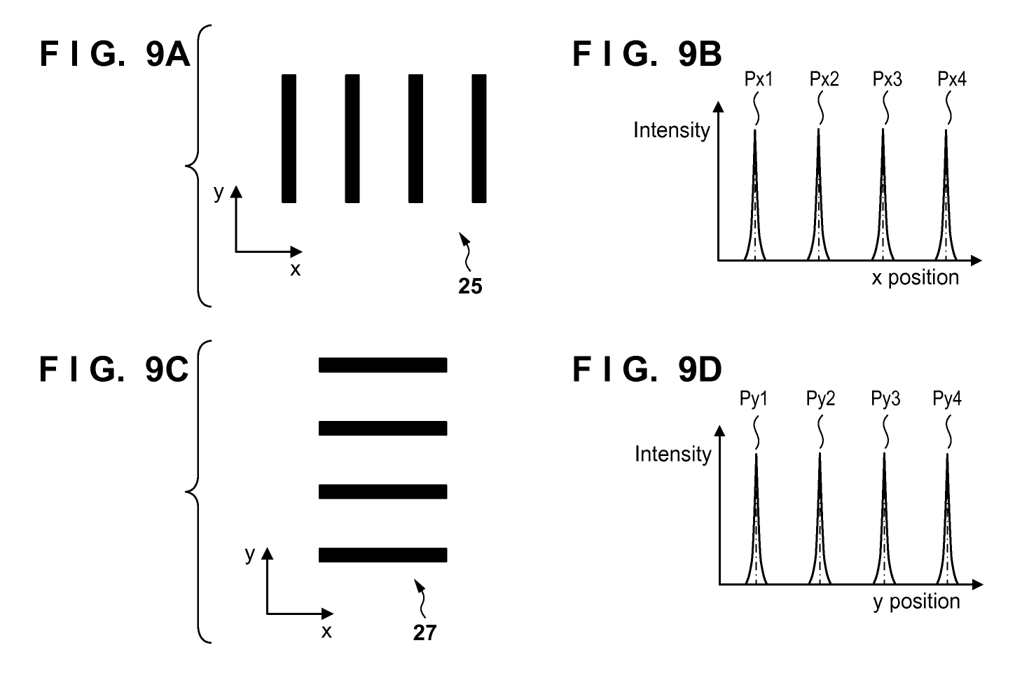

A practical example will be given below with reference to FIGS. 6A, 6B, and 9A to 9D. FIG. 9A shows an image of an alignment mark 25 for position detection in the X-direction, shown in FIG. 6A, which is formed on the detection surface of a photoelectric converter of the alignment scope 22. FIG. 9B shows the waveform of a detection signal output from the photoelectric converter of the alignment scope 22 as the alignment mark 25 is observed. FIG. 9C shows an image of an alignment mark 27 for position detection in the Y-direction, shown in FIG. 6B, which is formed on the detection surface of the photoelectric converter of the alignment scope 22. FIG. 9D shows the waveform of a detection signal output from the photoelectric converter of the alignment scope 22 as the alignment mark 27 is observed.

The positions of peaks Px1, Px2, Px3, and Px4 in the detection signal illustrated in FIG. 9B indicate those of four linear patterns which form the alignment mark 25. A processor 41 calculates the average of the positions of the peaks Px1, Px2, Px3, and Px4 as the position of the alignment mark 25 on the photoelectric converter in accordance with:

X_position=(Px1+Px2+Px3+Px4)/4 (3)

The processor 41 performs operations including control of a driving unit included in the alignment scope 22, ON/OFF control of a light source, and processing of a detection signal. A detection signal can be processed based on measurement process parameters in that case. These measurement process parameters can include parameters for controlling the operation of the photoelectric converter. The processor 41 can be configured to receive a plurality of detection signals (these signals are updated continually) output from the photoelectric converter, calculate X position in accordance with equation (3) based on each received detection signal, and average the calculation results, thereby obtaining the final value of X_position. This means that the processor 41 is configured to measure the position of each individual alignment mark 25 a plurality of times, and average a plurality of measurement results obtained by the repetitions of measurement, thereby detecting the position of the alignment mark 25. With this operation, detection errors included in the detection signals due to minute vibration of a substrate stage 218, and detection errors due, for example, to electrical noise can be reduced by an averaging effect.

The positions of peaks Py1, Py2, Py3, and Py4 in the detection single illustrated in FIG. 9D indicate those of four linear patterns which form the alignment mark 27. The processor 41 calculates the average of the positions of the peaks Py1, Py2, Py3, and Py4 as the position of the alignment mark 27 on the photoelectric converter in accordance with:

Y_position=(Py1+Py2+Py3+Py4)/4 (4)

The processor 41 can be configured to receive a plurality of detection signals (these signals are updated continually) output from the photoelectric converter, calculate Y position in accordance with equation (4) based on each received detection signal, and average the calculation results, thereby obtaining the final value of Y_position. This means that the processor 41 is configured to measure the position of each individual alignment mark 27 a plurality of times, and average a plurality of measurement results obtained by the repetitions of measurement, thereby detecting the position of the alignment mark 27.

As the measurement count of each individual alignment mark to be averaged increases, the position detection precision of this alignment mark improves and, eventually, the alignment precision also improves. Hence, the measurement process control unit 260 determines the measurement count of each individual alignment mark 25 in detecting the position of this alignment mark 25 in the X-direction, based on the first required alignment precision in the X-direction. Similarly, the measurement process control unit 260 determines the measurement count of each individual alignment mark 27 in detecting the position of this alignment mark 27 in the Y-direction, based on the second required alignment precision in the Y-direction.

Assume herein that upon expression of the alignment precisions as size errors, the first required alignment precision (size error) in the X-direction is 1/n the second required alignment precision (size error) in the Y-direction. In this case, the measurement count for averaging in the X-direction is preferably n² times that for averaging in the Y-direction. For example, the measurement reproducibility precision (size error) of the alignment scope 22 is assumed to be 100 nm. Also, the second required alignment precision (size error) in the Y-direction is assumed to be 100 nm, and the first required alignment precision (size error) in the X-direction is assumed to be two times stricter than in the Y-direction, that is, 50 nm. In this case, when the measurement count in the Y-direction is 1, and the measurement count in the X-direction is 2²=4, measurement can be done while a first required alignment precision (size error) of 100 nm/4=50 nm is satisfied.

The charge accumulation time taken for the photoelectric converter of the alignment scope 22 to acquire the information of each individual alignment mark by photoelectric conversion also influences the position detection precision (and, eventually the alignment precision). Prolonging the charge accumulation time makes it possible to average minute fluctuations in the detection signals due to the influence of minute vibration of the substrate stage 218 or disturbance, thereby reducing detection errors. Hence, the measurement process control unit 260 may determine the charge accumulation time taken for the photoelectric converter to acquire the pieces of information of the alignment marks 25 in the X-direction, based on the first required alignment precision in the X-direction. Similarly, the measurement process control unit 260 may determine the charge accumulation time taken for the photoelectric converter to acquire the pieces of information of the alignment marks 27 in the Y-direction, based on the second required alignment precision in the Y-direction. Assume herein that upon expression of the alignment precisions as size errors, the first required alignment precision (size error) in the X-direction is 1/n the second required alignment precision (size error) in the Y-direction. In this case, the charge accumulation time taken to detect the positions of the alignment marks in the X-direction is preferably n² times that taken to detect the positions of the alignment marks in the Y-direction.

### Third Embodiment

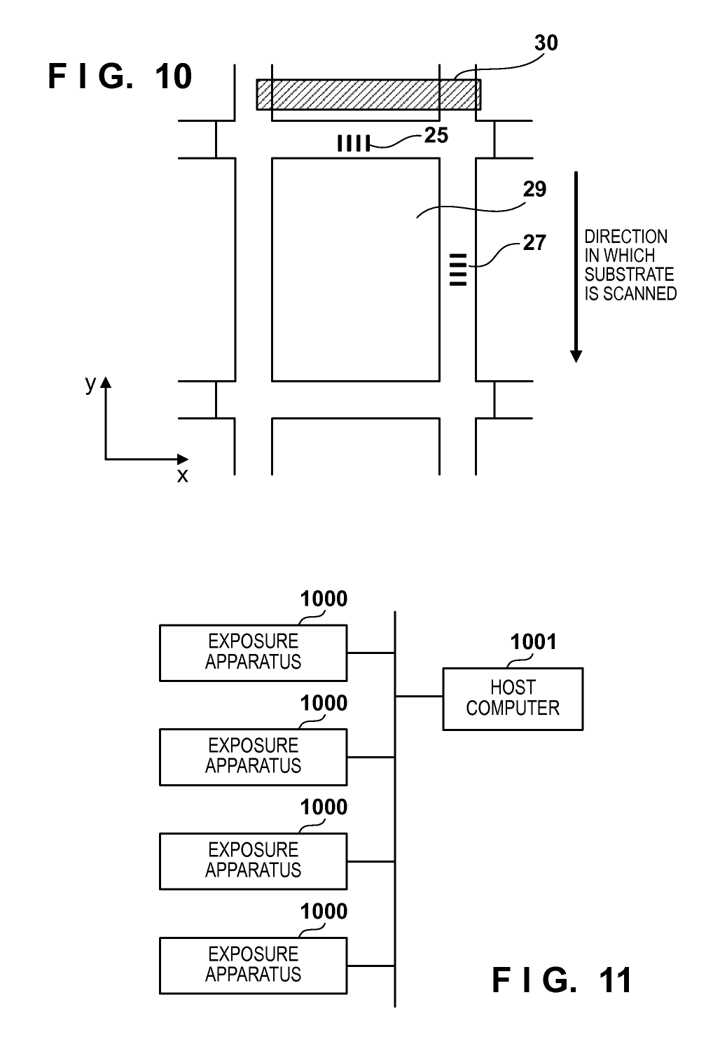

The third embodiment of the present invention will be described with reference to FIG. 10. The third embodiment relates to a method of drawing alignment marks using a charged particle beam exposure apparatus. FIG. 10 shows the result of scanning a substrate 217 from the positive Y-direction to the negative Y-direction relative to an area 30 in which a pattern is drawn with a plurality of charged particle beams. Referring to FIG. 10, a wiring pattern (not shown) in a shot region 29, an alignment mark 25 for measurement in the X-direction, and an alignment mark 27 for measurement in the Y-direction are drawn. In the process of scan drawing, as for the alignment marks alone, the alignment mark 27 is drawn first, and the alignment mark 25 is drawn next. In this manner, the alignment mark 25 for measurement in the X-direction, and the alignment mark 27 for measurement in the Y-direction are drawn at different timings.

### Fourth Embodiment

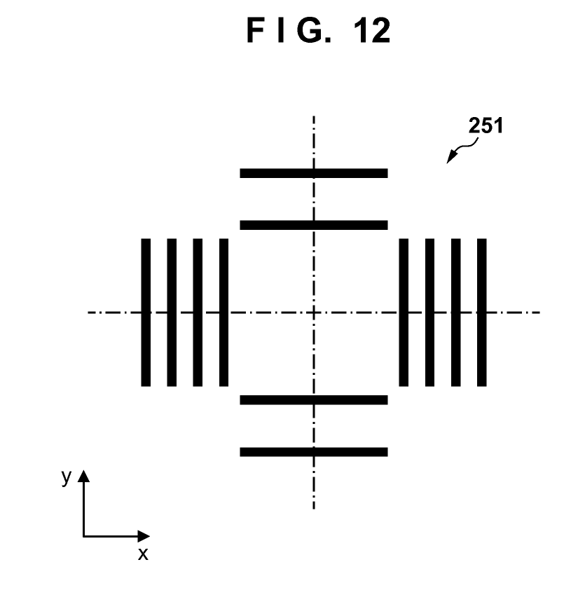

The fourth embodiment of the present invention will be described with reference to FIG. 11. The fourth embodiment relates to a lithography system including a plurality of exposure apparatuses 1000 and one host computer 1001. Although the plurality of exposure apparatuses 1000 each can serve as, for example, the charged particle beam exposure apparatus illustrated in FIG. 2, they can serve as other types of exposure apparatuses. The host computer 1001 can serve as, for example, the computer 200 illustrated in FIG. 2. When the plurality of exposure apparatuses 1000 perform the same process, the host computer 1001 sends first and second required alignment precisions to the plurality of exposure apparatuses 1000. The first and second required alignment precisions are acquired by an acquisition unit (corresponding to the above-mentioned acquisition unit 280) provided in each exposure apparatus. When first and second conditions corresponding to the first and second required alignment precisions, respectively, are determined in either exposure apparatus 1000, the first and second conditions can be sent to other exposure apparatuses 1000 via the host computer 1001.

### Embodiment of Method of Manufacturing Article

A method of manufacturing an article according to an embodiment is suitable for manufacturing various articles including a microdevice such as a semiconductor device and an element having a microstructure. This method can include a step of forming a pattern (for example, a latent image pattern) on an object (for example, a substrate having a photosensitive material applied on its surface) using the above-mentioned lithography apparatus, and a step (for example, a development step) of processing the object having the pattern formed on it in the forming step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

Note that alignment marks 25 and 27 may be a (two dimensional) mark (such as a mark 251 shown in FIG. 12) of which a two dimensional position (x-coordinate and y-coordinate) can be measured. In this case, calculation of x-coordinate or y-coordinate of a selected mark (of a plurality of the two dimensional mark) can be omitted in accordance with the first and second required alignment precisions.

This application claims the benefit of Japanese Patent Application No. 2011-272748 filed Dec. 13, 2011 and No. 2012-260341 filed Nov. 28, 2012, which are hereby incorporated by reference herein in their entirety.

What is claimed is:

1. A lithography apparatus which positions a substrate based on measurement of a position of an alignment mark formed on the substrate to form a pattern on the substrate, the apparatus comprising:
an acquisition unit configured to acquire a first required alignment precision in a first direction, and a second required alignment precision in a second direction different from the first direction; and
a controller configured to determine, based on the first required alignment precision, a first condition for a first measurement process of measuring a position of an alignment mark in the first direction, to determine, based on the second required alignment precision, a second condition for a second measurement process of measuring a position of an alignment mark in the second direction, to control execution of the first measurement process in accordance with the first condition, and to control execution of the second measurement process in accordance with the second condition.

2. The apparatus according to claim 1, wherein
the first condition includes number of alignment marks of which positions in the first direction are to be measured, and the second condition includes number of alignment marks of which positions in the second direction are to be measured, and
the controller is configured to determine the first condition and the second condition such that the number of alignment marks of which positions in the first direction are to be measured is different from the number of alignment marks of which positions in the second direction are to be measured, if the first required alignment precision is different from the second required alignment precision.

3. The apparatus according to claim 1, wherein
each of the first measurement process and the second measurement process includes a process of measuring a position of an alignment mark a plurality of times, and averaging the plurality of measured positions to obtain the position of the alignment mark,
each of the first condition and the second condition includes number of the plurality of times, and
the controller is configured to determine the first condition and the second condition such that the number of the plurality of times for the alignment marks of which position in the first direction is to be measured is different from the number of the plurality of times for the alignment mark of which positions in the second direction is to be measured, if the first required alignment precision is different from the second required alignment precision.

4. The apparatus according to claim 1, wherein
each of the first condition and the second condition includes a charge accumulation time taken to acquire information of the alignment mark by photoelectric conversion, and
the controller is configured to determine the first condition and the second condition such that the charge accumulation time for the alignment marks of which position in the first direction is to be measured is different from the charge accumulation time for the alignment mark of which positions in the second direction is to be measured, if the first required alignment precision is different from the second required alignment precision.

5. A lithography method of positioning a substrate based on measurement of a position of an alignment mark formed on the substrate to form a pattern on the positioned substrate, the method comprising:
acquiring a first required alignment precision in a first direction, and a second required alignment precision in a second direction different from the first direction;
determining, based on the first required alignment precision, a first condition for a first measurement process of measuring a position of an alignment mark in the first direction, and determining, based on the second required alignment precision, a second condition for a second measurement process of measuring a position of an alignment mark in the second direction; and
executing the first measurement process in accordance with the first condition, and executing the second measurement process in accordance with the second condition.

6. A method of manufacturing an article, the method comprising:
forming a pattern on a substrate using a lithography apparatus; and
processing the substrate, on which the pattern has been formed, to manufacture the article,
wherein the lithography apparatus positions the substrate based on measurement of a position of an alignment mark formed on the substrate to form the pattern on the substrate, the apparatus including:
an acquisition unit configured to acquire a first required alignment precision in a first direction, and a second required alignment precision in a second direction different from the first direction; and
a controller configured to determine, based on the first required alignment precision, a first condition for a first measurement process of measuring a position of an alignment mark in the first direction, to determine, based on the second required alignment precision, a second condition for a second measurement process of measuring a position of an alignment mark in the second direction, to control execution of the first measurement process in accordance with the first condition, and to control execution of the second measurement process in accordance with the second condition.
